(19) United States
(12) Patent Application Publication
(10) Pub. No.: US 2007/0126353 A1
(43) Pub. Date: Jun. 7, 2007

(54) DISPLAY

(76) Inventors: Hirofumi Kubota, Kanazawa-shi (JP); Satoshi Okutani, Ishikawa-gun (JP); Tsuyoshi Uemura, Kanazawa-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/671,270

(22) Filed: Feb. 5, 2007

Related U.S. Application Data
(63) Continuation of application No. PCT/JP05/16879, filed on Sep. 7, 2005.

(30) Foreign Application Priority Data
Sep. 28, 2004 (JP) 2004-282678

(51) Int. Cl. H01L 51/00

(52) U.S. Cl. 313/506

(57) ABSTRACT

A display includes a light-emitting element which includes a back electrode, a front electrode facing the back electrode, and an active layer interposed therebetween and including an emitting layer, and a light-scattering layer which is placed on a front side of the front electrode. The light-emitting element forms at least a portion of a microcavity structure. A forward-scattered light is greater in luminous energy than a back-scattered light when the light-scattering layer is irradiated with light from the microcavity structure.

### CROSS REFERENCE TO RELATED APPLICATIONS

This is a Continuation Application of PCT Application No. PCT/JP2005/016879, filed Sep. 7, 2005, which was published under PCT Article 21(2) in English.

This application is based upon and claims the benefit of priority from prior Japanese Patent Application No. 2004-282678, filed Sep. 28, 2004, the entire contents of which are incorporated herein by reference.

### BACKGROUND OF THE INVENTION

1. Field of the Invention

The present invention relates to a display.

2. Description of the Related Art

Since organic electroluminescent (EL) displays are of a self-emission type, they have a wide viewing angle and high-speed response. Further, they need no backlights, and hence can be made low-profile and lightweight. For these reasons, attention has recently been paid to them as displays that may replace liquid crystal displays.

As the current flowing through the organic EL elements of organic EL displays is increased, the luminance of the displays is increased. In this case, however, the power consumption of the display is increased, and its life time is greatly shortened. To simultaneously realize high luminance, low power consumption and long life time, it is important to efficiently extract the light generated in each organic EL element from the organic EL display, namely, to enhance the outcoupling efficiency.

### BRIEF SUMMARY OF THE INVENTION

An object of the invention is to enhance the outcoupling efficiency of organic EL displays.

According to a first aspect of the present invention, there is provided a display comprising a light-emitting element which comprises a back electrode, a front electrode facing the back electrode, and an active layer interposed between the back and front electrodes and including an emitting layer, and a light-scattering layer which is disposed on a front side of the front electrode, wherein the light-emitting element forms at least a portion of a microcavity structure, and wherein a forward-scattered light is greater in luminous energy than a back-scattered light when the light-scattering layer is irradiated with light from the microcavity structure.

### BRIEF DESCRIPTION OF THE SEVERAL VIEWS OF THE DRAWING

FIG. 1 is a sectional view schematically showing an organic EL display according to an embodiment of the invention;

FIG. 2 is a sectional view schematically showing a modification of the organic EL display shown in FIG. 1; and

FIG. 3 is a sectional view schematically showing another modification of the organic EL display shown in FIG. 1.

### DETAILED DESCRIPTION OF THE INVENTION

An embodiment of the present invention will be described below in detail with reference to the accompanying drawings. The same reference numerals denote the same or similar constituent elements throughout the drawings, and a repetitive description thereof will be omitted.

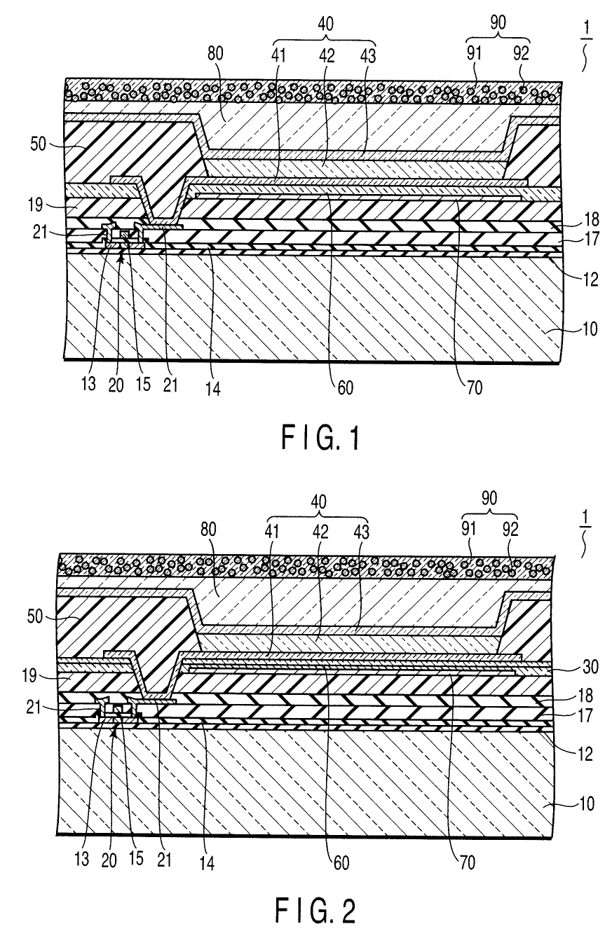

FIG. 1 is a sectional view schematically showing an organic EL display according to an embodiment of the invention. In FIG. 1, the display surface, i.e., the front surface or light emission surface, of the organic EL display is upwardly directed, and the back surface of the display is downwardly directed.

The organic EL display 1 shown in FIG. 1 is of a top emission type that employs an active matrix driving method.

The organic EL display 1 includes an insulating substrate 10 made of, for example, glass.

A plurality of pixels are arranged in a matrix on the insulating substrate 10. Each pixel includes a pixel circuit and organic EL element 40.

The pixel circuit includes, for example, a drive control element (not shown) and output control switch 20 connected in series with the organic EL element 40 between a pair of power supply terminals, and a pixel switch (not shown). The drive control element has its control terminal connected to a video signal line (not shown) via the pixel switch, and supplies a current, corresponding to a video signal from the video signal line, to the organic EL element 40 through the output control switch 20. The control terminal of the pixel switch is connected to a scan signal line (not shown), and has its switching operation controlled by a scanning signal from the scan signal line. The pixels may have another structure.

On the substrate 10, an SiNₓ layer and SiOₓ layer, for example, are stacked in this order and serve as an undercoat layer 12. On the undercoat layer 12, a semiconductor layer 13, gate insulator 14 and gate electrode 15 are stacked in this order. The semiconductor layer 13 is, for example, a polysilicon layer in which a channel, source and drain are formed. The gate insulator 14 is made from, for example, tetraethyl orthosilicate (TEOS). The gate electrode 15 is made of, for example, MoW. These layers provide a top gate type thin-film transistor (hereinafter referred to as “the TFT”). In this example, the TFTs are used for the pixel switch, output control switch 20 and drive control element. Further, on the gate insulator 14, scan signal lines (not shown), which can be formed in the same step as that of the gate electrode 15, are arranged.

An interlayer insulating film 17 made of, for example, SiOₓ is formed by plasma CVD on the gate insulator 14 and gate electrode 15. Source and drain electrodes 21 are arranged on the interlayer insulating film 17, and buried in a passivation film 18 made of, for example, SiNₓ. The source and drain electrodes 21 have a three-layer structure of, for example, Mo/Al/Mo, and electrically connected to the source and drain of the TFT via a contact hole formed in the interlayer insulating film 17. Further, on the interlayer insulating film 17, video signal lines (not shown), which can be formed in the same step as that for the source and drain electrodes 21, are arranged.

A flattening layer 19 is formed on the passivation film 18. A reflection layer 70 is formed on the flattening layer 19. The flattening layer 19 may be made of a hard resin. The reflection layer 70 may be made of a metal such as Al.

A flattening layer 60 is formed on the flattening layer 19 and reflection layer 70. The flattening layer 60 serves as a flat underlayer for the organic EL element 40. The flattening layer 60 may be made of a transparent resin, such as silicone resin or acryl resin.

On the flattening layer 60, first electrodes 41 with light-transmission property are arranged apart from one another. The first electrodes 41 face the reflection layers 70. Each first electrode 41 is connected to the drain electrode 21 via through holes formed in the passivation film 18 and flattening layers 19 and 60.

In this example, the first electrodes 41 serve as anodes as back electrodes. The electrodes 41 may be made of a transparent conductive oxide, such as indium tin oxide (ITO).

A partition insulating layer 50 is formed on the flattening layer 60. A through hole is formed in the partition insulating layer 50 at a position corresponding to each first electrode 41. The partition insulating layer 50 is, for example, an organic insulating layer and can be formed by photolithography.

On the portion of each first electrode 41 exposed in the corresponding through hole of the partition insulating layer 50, an organic layer 42 including a light-emitting layer is formed as an active layer. The light-emitting layer is, for example, a thin film containing a luminescent organic compound that emits red, green, or blue light. The organic layer 42 may also include a layer other than the light emitting layer. For example, the organic layer 42 may also include a buffer layer that permits holes to be injected from the corresponding first electrode 41 into the light emitting layer. The organic layer 42 may also include a hole transporting layer, blocking layer, electron transporting layer, and electron injection layer, etc.

A second electrode 43 with light-reflection property is formed on the partition insulating layer 50 and organic layers 42. In this example, the second electrode 43 is a front electrode as a cathode that continuously extends over all pixels and serves as a common electrode for all pixels. The second electrode 43 is electrically connected to electrode interconnections, which are formed on the same layer as the video signal lines, via contact holes (not shown) formed in the passivation film 18, flattening layer 19, outcoupling layer 30, flattening layer 60 and partition insulating layer 50.

Each organic EL element 40 includes the first electrode 41, organic layer 42, and second electrode 43. In this example, assume that a structure in which an ITO layer, a CuPc layer, α-NPD layer, Alq₃ layer, LiF layer and ITO layer are stacked in this order is used as the organic EL element 40.

On the second electrode 43, a protective film 80 with light-transmission property is formed. The protective film 80 prevents external moisture or oxygen from coming in contact with the organic EL elements. The protective film 80 may be made of a transparent dielectric such as SiNₓ.

A light-scattering layer 90 is formed on the protective film 80. The light-scattering layer 90 includes a transparent region 91 and particulate regions 92 distributed in the transparent region 91 and having optical characteristics different from those of the region 91.

A forward scattering property of the light-scattering layer 90 is a greater than a back scattering property of the light-scattering layer 90. More specifically, when light is emitted from a microcavity structure, described later, to the light-scattering layer 90, the forward-scattered light is greater in luminous energy than the back-scattered light. The luminous energy ratio (hereinafter referred to as “the forward-scattering ratio”) of the forward-scattered light to the light emitted from the microcavity structure is typically 60% or more. For example, the forward-scattering ratio of the light-scattering layer 90 is 80% or more.

The light-scattering layer 90 may be made of, for example, an organic substance with metal fine particles and/or oxide particles distributed therein. TiO₂ particles with a particle diameter of 20 to 200 nm may be used as such particles.

In general, the organic EL display 1 shown in FIG. 1 includes a polarizer arranged on the front side of the organic EL element 40, typically, the front side of the light-scattering layer 90. Further, although the organic EL display 1 employs sealing using the protective film, it may employ sealing using glass.

In the organic EL display 1, the organic EL element 40 forms at least a portion of the microcavity (micro-optical resonator) structure in which the light emitted from its light-emitting layer resonates. Accordingly, in the organic EL display 1, the light forwardly emitted by the organic EL element 40 has high intensity and high directivity.

Therefore, if there is no light-scattering layer 90, most of the light forwardly emitted from the organic EL element 50 passes through the protective film 80 instead of being reflected or totally reflected by the film 80. However, unless the light-scattering layer 90 is provided, it is difficult for the organic EL display 1 to realize a sufficient viewing angle, since the light forwardly emitted from the organic EL element 40 has high directivity.

In the organic EL display 1 of FIG. 1, the light-scattering layer 90 is located in front of the organic EL element 40, therefore achieves a wide viewing angle.

Where the light-scattering layer 90 is located in front of the organic EL element 40, part of the light emitted from the element 40 scatters rearward and enters the element 40. Part of the light entering the organic EL element 40 contributes to the resonance in the microcavity structure, while most of the remaining part of the back-scattered light is absorbed by various components of the display.

In light of the above, the embodiment uses, as the light-scattering layer 90, a layer with a forward-scattering ratio of 50% or more. For instance, a light-scattering layer 90 with a forward-scattering ratio of 80% or more is used. In this case, the luminous energy ratio (hereinafter referred to as “the back-scattering ratio”) of the back-scattered light to the light emitted from the microcavity structure is 20% at maximum. From the fact that the back-scattering ratio is 20% and that a third of the back-scattered light contributes to the resonance in the microcavity structure, it is understood that about 86% of the light forwardly emitted from the microcavity structure can be utilized for display. Accordingly, a wide viewing angle and high intensity can be simultaneously realized.

Typically, a light-scatting layer 90 with a forward-scattering ratio of 60% or more is used. In this case, if the back-scattering ratio is 40% and a third of the back-scattered light contributes to the resonance in the microcavity structure, about 73% of the light forwardly emitted from the microcavity structure can be utilized for display.

If the back-scattering ratio of the light-scattering layer 90 is more than 40%, e.g., equal to or more than 41%, the degree of scatter of extraneous light by the light-scatting layer 90 is high. Accordingly, in this case, sufficient visibility may not be achieved.

The above-described organic EL display 1 can be modified in various ways.

FIG. 2 is a schematic sectional view showing a modification of the organic EL display 1 of FIG. 1.

This organic EL display 1 includes an outcoupling layer 30 between the reflection layer 70 and first electrodes 41. Except for this, the organic EL display 1 shown in FIG. 2 has the same structure as that of the organic EL display 1 shown in FIG. 1.

Part of the light emitted from the light-emitting layer repeatedly reflects in the waveguide layer including the first electrode 41 and organic layer 42, i.e., the microcavity structure, and propagates in the direction of the film surface. The light propagating in the direction of the film surface cannot be extracted from the waveguide layer if the incident angle of the light with respect to the main surface of the waveguide layer is large.

When the outcoupling layer 30 is placed near the organic EL element 40, the traveling direction of the light emitted from the light-emitting layer is changed. That is, the outcoupling layer 30 enables the light emitted from the light-emitting layer to be extracted from the waveguide layer with higher efficiency.

The outcoupling layer 30 may be, for example, a diffraction grating layer. Most of the light emitted from the microcavity structure can travel substantially perpendicularly to the film surface by appropriately setting the grating constant of the diffraction grating in accordance with the color of the light, such as red, green or blue.

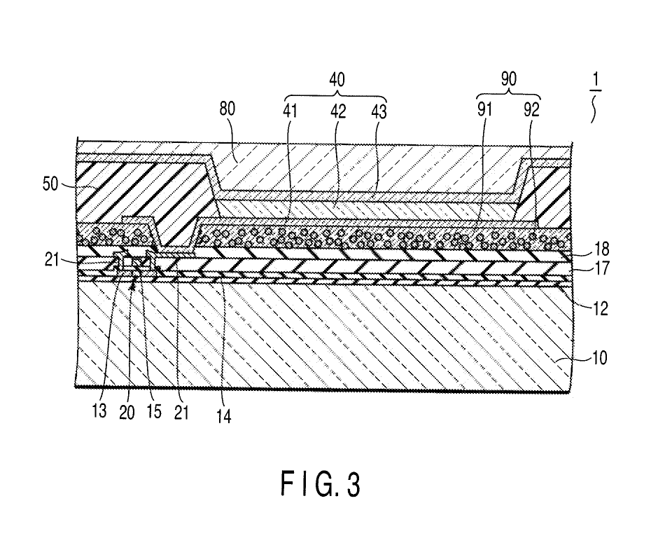

FIG. 3 is a sectional view schematically showing another modification of the organic EL display 1 of FIG. 1.

The organic EL display 1 of FIG. 3 is of a bottom-emission type. The organic EL display 1 of FIG. 3 has the same structure as that shown FIG. 1 except for the points described below. In the organic EL display 1 of FIG. 3, the reflection layer 70 and the flattening layers 19 and 60 are not employed, and the light-scattering layer 90 is interposed between the passivation film 18 and the first electrodes 41. Further, the second electrode 43 is a light-reflecting electrode.

As described above, the first electrodes 41 as front electrodes may be in contact with the light-scattering layer 90. The present invention is also applicable to the bottom-emission organic EL display.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A display comprising:
a light-emitting element which comprises a back electrode, a front electrode facing the back electrode, and an active layer interposed between the back and front electrodes and including an emitting layer; and
a light-scattering layer which is disposed on a front side of the front electrode,
wherein the light-emitting element forms at least a portion of a microcavity structure, and wherein a forward-scattered light is greater in luminous energy than a back-scattered light when the light-scattering layer is irradiated with light from the microcavity structure.

2. The display according to claim 1, wherein a ratio of a luminous energy of the forward-scattered light with respect to a luminous energy of the light from the microcavity structure is 60% or more.

3. The display according to claim 1, wherein a ratio of a luminous energy of the forward-scattered light with respect to a luminous energy of the light from the microcavity structure is 80% or more.

4. The display according to claim 1, wherein the light-scattering layer is in contact with the front electrode.

5. The display according to claim 1, further comprising an outcoupling layer which is disposed on a back side of the light-scattering layer and extracts a light propagating inside the microcavity structure in a direction parallel to a main surface of the active layer while causing multiple-beam interference from the microcavity structure to make the light travel in front of the light-emitting element.

6. The display according to claim 5, wherein the outcoupling layer is a diffraction grating layer.

7. The display according to claim 1, wherein the light-scattering layer comprises an organic material and particles made of metal or oxide and dispersed in the organic material.

8. The display according to any one of claims 1 to 7, wherein the light-emitting element is an organic EL element.
